(19) United States
(12) Patent Application Publication
(10) Pub. No.: US 2025/0392300 A1
(43) Pub. Date: Dec. 25, 2025

(54) SEMICONDUCTOR DEVICE

(71) Applicant: FUJI ELECTRIC CO., LTD., Kawasaki-shi (JP)

(72) Inventor: Masahiro TAOKA, Matsumoto-city (JP)

(73) Assignee: FUJI ELECTRIC CO., LTD., Kawasaki-shi (JP)

(21) Appl. No.: 19/221,263

(22) Filed: May 28, 2025

(30) Foreign Application Priority Data
Jun. 25, 2024 (JP) 2024-102396

(51) Int. Cl. H03K 17/0812; H03K 17/08

(52) U.S. Cl. CPC H03K 17/08128; H03K 2017/0806

(57) ABSTRACT

A semiconductor device, including: a switching element having a gate; a gate drive circuit configured to drive the switching element; a voltage output element configured to detect a temperature of the switching element when the switching element is driven and output a voltage corresponding to the temperature; and a drive capability control circuit configured to control a drive capability of the switching element by changing a gate drive voltage to be applied to the gate of the switching element based on the voltage outputted by the voltage output element.

### CROSS-REFERENCE TO RELATED APPLICATION

This application is based upon and claims the benefit of priority of the prior Japanese Patent Application No. 2024-102396, filed on Jun. 25, 2024, the entire contents of which are incorporated herein by reference.

### BACKGROUND OF THE INVENTION

### 1. Field of the Invention

The embodiment discussed herein relates to a semiconductor device.

### 2. Background of the Related Art

Semiconductor devices called intelligent power modules (IPMs) have been developed, which include power semiconductor elements such as insulated gate bipolar transistors (IGBTs), drive circuits for driving the power semiconductor elements, and so on.

As related techniques, for example, there has been proposed a technique of increasing the gate resistance of a semiconductor element when the temperature of the semiconductor element becomes higher than a specified temperature and decreasing the gate resistance of the semiconductor element when the temperature of the semiconductor element becomes lower than the specified temperature (see, for example, Japanese Laid-open Patent Publication No. 2016-127435). Further, there has been proposed a technique of increasing the resistance value of a gate resistor of a power element chip when the temperature detected by a thermistor built in the power element chip is equal to or lower than a predetermined value, thereby increasing a loss at the time of switching of the power element chip to raise the temperature (see, for example, Japanese Laid-open Patent Publication No. 2003-007934).

Still further, a technique has been proposed in which the switching speed of a switching element is maintained at a first speed when the temperature of the switching element is equal to or lower than a predetermined temperature, and the switching speed is changed to a second speed higher than the first speed when the temperature of the switching element is higher than the predetermined temperature (see, for example, Japanese Laid-open Patent Publication No. 2004-096318).

Still further, there has been proposed a technique of changing a current amount of constant current output from a constant current supply unit that drives a switching element, to switch the drive capability of the switching element (see, for example, Japanese Laid-open Patent Publication No. 2023-175239). Still furthermore, there has been proposed a technique of performing a correction operation of a measurement value output from an analog-to-digital (A/D) converter at the time of temperature measurement by a temperature detection diode and calculating a gradient of a line segment based on the characteristics of a chip temperature detecting circuit (see, for example, Japanese Laid-open Patent Publication No. 2013-057550).

### SUMMARY OF THE INVENTION

According to an aspect of the present disclosure, there is provided a semiconductor device including: a switching element having a gate; a gate drive circuit configured to drive the switching element; a voltage output element configured to detect a temperature of the switching element when the switching element is driven and output a voltage corresponding to the temperature; and a drive capability control circuit configured to control a drive capability of the switching element by changing a gate drive voltage to be applied to the gate of the switching element based on the voltage outputted by the voltage output element.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a diagram for describing an example of a semiconductor device;

FIG. 2 is a diagram for describing the operation of drive capability control;

FIG. 3 illustrates an example of waveforms when a switching element is turned on;

FIG. 4 illustrates an example of the temperature dependence of switching loss;

FIG. 5 illustrates an example of a configuration of a semiconductor device according to a reference example;

FIG. 6 illustrates an example of a first configuration of a semiconductor device according to the present embodiment;

FIG. 7 is a diagram for describing the operation of the drive capability control when an insulated gate bipolar transistor (IGBT) s in an ambient-temperature state;

FIG. 8 is a diagram for describing the operation of the drive capability control when the IGBT is in a high-temperature state;

FIG. 9 illustrates a first mounting example of circuit components of a semiconductor chip;

FIG. 10 illustrates a second mounting example of circuit components of a semiconductor chip; and

FIG. 11 illustrates an example of a second configuration of a semiconductor device according to the present embodiment.

### DETAILED DESCRIPTION OF THE INVENTION

Hereinafter, one embodiment will be described with reference to the drawings. Note that, in this description and the accompanying drawings, structural elements that have substantially the same structure are denoted with the same reference numeral, and repeated description of these structural elements may be omitted.

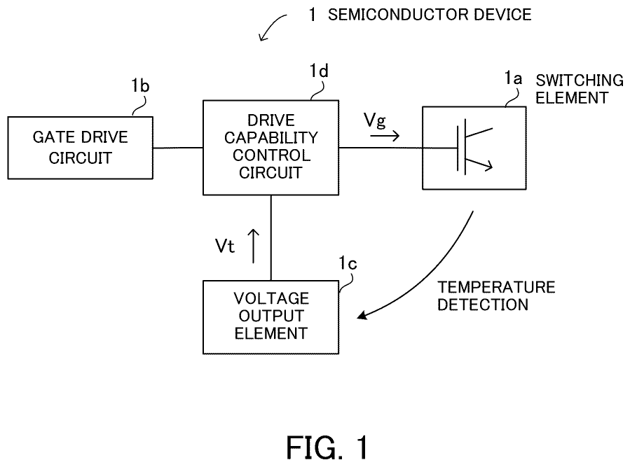

FIG. 1 is a diagram for describing an example of a semiconductor device. The semiconductor device 1 includes a switching element 1a, a gate drive circuit 1b, a voltage output element 1c, and a drive capability control circuit 1d. The switching element 1a is a voltage-driven switching element, and may be an insulated gate bipolar transistor (IGBT) or a power metal-oxide-semiconductor field-effect transistor (MOSFET).

The gate drive circuit 1b drives the switching element 1a. The voltage output element 1c detects the temperature of the switching element 1a when the switching element 1a is driven, and outputs a voltage Vt corresponding to the temperature. For example, the voltage output element 1c is able to generate a thermoelectromotive force corresponding to the temperature and output the voltage Vt. The drive capability control circuit 1d controls the drive capability of the switching element 1a by changing the gate drive voltage Vg to be applied to the gate of the switching element 1a on the basis of the voltage Vt.

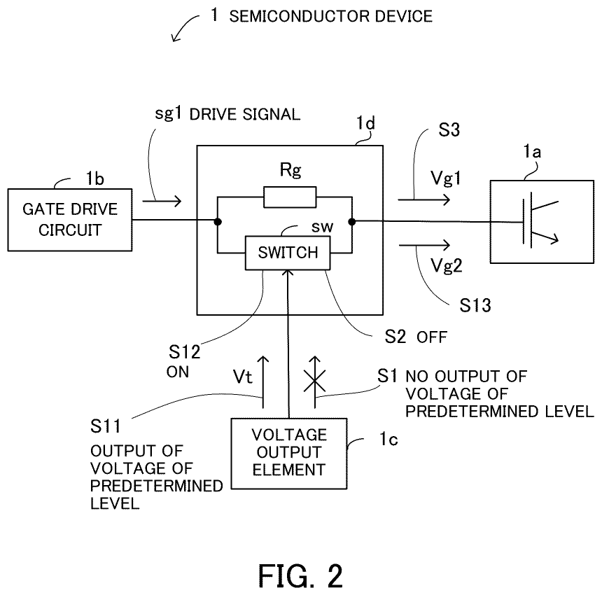

FIG. 2 is a diagram for describing the operation of the drive capability control. The drive capability control circuit 1d includes a gate resistor Rg and a switch sw that is connected in parallel to the gate resistor Rg and is turned on and off in response to the voltage Vt.

[Step S1] When the switching element 1a is in a first-temperature state (ambient-temperature state) corresponding to a first temperature, the voltage output element 1c detects the first temperature of the switching element 1a and, in this case, does not output a voltage of a predetermined level. The voltage Vt is at a low level with respect to the switch sw.

[Step S2] The switch sw is turned off when the voltage Vt is at the low level.

[Step S3] Since a drive signal sg1 output from the gate drive circuit 1b flows through the gate resistor Rg, the drive capability control circuit 1d generates a gate drive voltage Vg1 (first gate drive voltage) based on the resistance value of the gate resistor Rg. Then, the drive capability control circuit 1d applies the gate drive voltage Vg1 to the gate of the switching element 1a to drive the switching element 1a with a first drive capability.

[Step S11] When the switching element 1a is in a second-temperature state (high-temperature state) corresponding to a second temperature higher than the first temperature, the voltage output element 1c detects the second temperature of the switching element 1a, and the voltage Vt of the predetermined level changes to a high level with respect to the switch sw.

[Step S12] The switch sw is turned on when the voltage Vt is at the high level.

[Step S13] Since the drive signal sg1 output from the gate drive circuit 1b flows through the gate resistor Rg and the switch sw, the drive capability control circuit 1d generates a gate drive voltage Vg2 (second gate drive voltage) based on the combined resistance value of the gate resistor Rg and the on-resistance of the switch sw.

Then, the drive capability control circuit 1d applies the gate drive voltage Vg2 to the gate of the switching element 1a to drive the switching element 1a with a second drive capability at a switching speed higher than the switching speed at the time of the first drive capability.

As described above, in the semiconductor device 1, the voltage output element outputs a voltage corresponding to the temperature of the switching element when the switching element is driven, and the gate drive voltage is changed based on the voltage, so as to control the drive capability of the switching element. Adjusting the drive capability on the basis of the temperature of the switching element enables a reduction in switching loss. In addition, it is possible to reduce the circuit mounting scale.

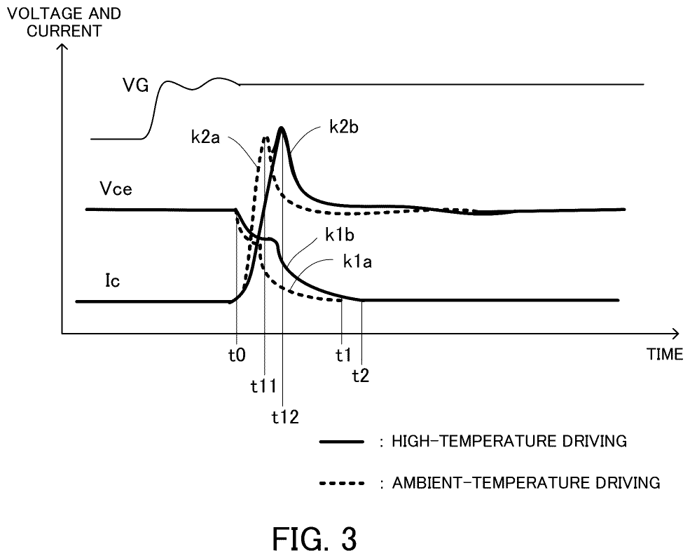

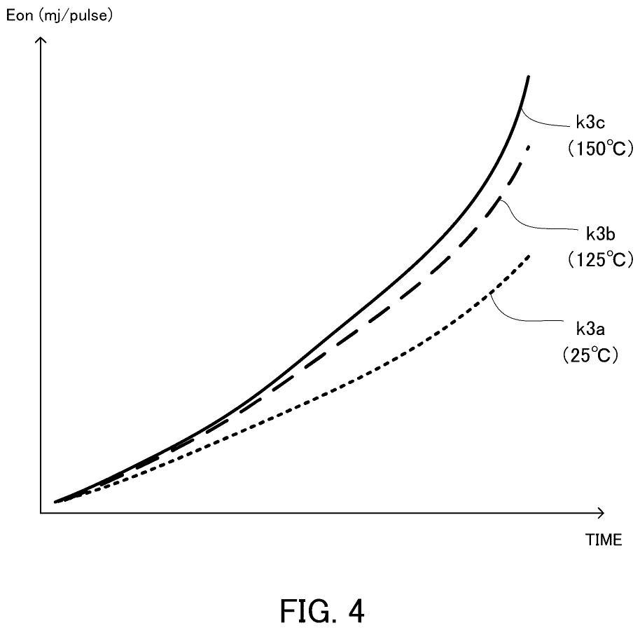

Next, the temperature dependence of the switching element during switching drive will be described with reference to FIGS. 3 and 4. In the following description, it is assumed that an IGBT is used as the switching element.

FIG. 3 illustrates an example of waveforms when the switching element is turned on. The horizontal axis represents time, and the vertical axis represents voltage and current. The illustrated waveforms are those of the collector-emitter voltage Vce and the collector current Ic when the gate drive voltage VG transitions from an L level to an H level and the IGBT is turned on.

The dotted waveform k1a of the collector-emitter voltage Vce and the dotted waveform k2a of the collector current Ic are waveforms when the IGBT is driven at ambient temperature. The solid waveform k1b of the collector-emitter voltage Vce and the solid waveform k2b of the collector current Ic are waveforms when the IGBT is driven at high temperature.

The ambient-temperature waveform k1a of the collector-emitter voltage Vce indicates that the high voltage level starts to gradually decrease at time t0 and reaches a constant low voltage level at time t1. On the other hand, the high-temperature waveform k1b indicates that the high voltage level starts to decrease at time to and reaches the constant low voltage level at time t2 (t1<t2). That is, when the IGBT is in the high-temperature state, the collector-emitter voltage Vce takes a longer time to reach the low voltage level than in the ambient-temperature state.

The ambient-temperature waveform k2a of the collector current Ic indicates that the amount of the current reaches a peak at time t11. On the other hand, the high-temperature waveform k2b indicates that the amount of the current reaches a peak at time t12 (t11<t12). That is, when the IGBT is in the high-temperature state, the collector current Ic takes a longer time to reach the peak than in the ambient-temperature state.

As described above, the switching drive of the IGBT depends on the temperature of the IGBT during the IGBT drive, and the switching speed of the IGBT in the high-temperature state is slower than that in the ambient-temperature state.

FIG. 4 illustrates an example of the temperature dependence of switching loss. The horizontal axis represents time, and the vertical axis represents switching loss Eon (mj/pulse). Waveforms k3a, k3b, and k3c indicate switching loss when the temperatures of the IGBT during IGBT switching drive are 25° C., 125° C., and 150° C., respectively. As illustrated in FIG. 4, the switching loss of the IGBT increases as the temperature of the IGBT increases during the IGBT switching drive.

As described above, when the IGBT is in a higher-temperature state during the IGBT switching drive, the switching speed of the IGBT becomes slower than the that in the ambient-temperature state, and the switching loss increases.

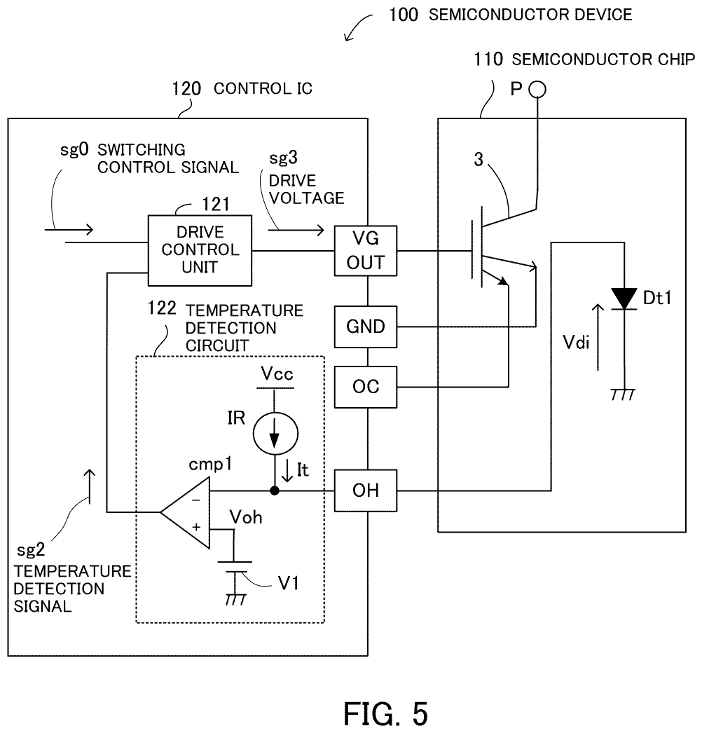

Next, a semiconductor device of a reference example will be described with reference to FIG. 5. FIG. 5 illustrates an example of a configuration of a semiconductor device according to the reference example. The semiconductor device 100 has an intelligent power module (IPM) function and includes a semiconductor chip 110 and a control integrated circuit (IC) 120.

The semiconductor chip 110 includes an IGBT 3, which is a switching element, and a temperature detection diode Dt1. The control IC 120 includes a drive control unit 121 and a temperature detection circuit 122. The temperature detection circuit 122 includes a constant current source IR, a comparator cmp1, and a reference voltage source V1.

The control IC 120 includes a terminal VGOUT, a terminal GND, a terminal OC, and a terminal OH. The terminal VGOUT is connected to the output terminal of the drive control unit 121 and the gate of the IGBT 3. The terminal GND serves as a ground terminal of the control IC 120, and the emitter of the IGBT 3 is connected to the terminal GND.

The terminal OC is a terminal for detecting a current flowing between the collector and the emitter of the IGBT 3, and is connected to the sense emitter of the IGBT 3. The terminal OH is a terminal for detecting the temperature of the IGBT 3 when the IGBT 3 is driven, and is connected to the output terminal of the constant current source IR, the inverting input terminal (−) of the comparator cmp1, and the anode of the temperature detection diode Dt1.

The collector of the IGBT 3 is connected to a positive terminal P, and the cathode of the temperature detection diode Dt1 is connected to GND. A power supply voltage Vcc is applied to the input terminal of the constant current source IR. The positive terminal of the reference voltage source V1 is connected to the non-inverting input terminal (+) of the comparator cmp1, and the negative terminal of the reference voltage source V1 is connected to GND.

The drive control unit 121 outputs a drive voltage sg3 for performing the ON-OFF switching control of the IGBT 3 on the basis of a switching control signal sg0 output from a control unit (not illustrated) such as a microcomputer. In addition, the drive control unit 121 has a function of controlling the drive capability of the IGBT 3 on the basis of the level of a temperature detection signal sg2 output from the temperature detection circuit 122.

The temperature detection circuit 122 detects the temperature of the IGBT 3 and outputs the temperature detection signal sg2 indicating the temperature detection result. While the temperature detection circuit 122 operates, a current It output from the constant current source IR flows through the temperature detection diode Dt1. At this time, the potential generated in the temperature detection diode Dt1 is input to the inverting input terminal (−) of the comparator cmp1 via the terminal OH as a temperature detection voltage Vdi indicating the temperature state of the IGBT 3.

A reference voltage Voh output from the reference voltage source V1 is applied to the non-inverting input terminal (+) of the comparator cmp1. The comparator cmp1 compares the temperature detection voltage Vdi with the reference voltage Voh, and detects based on the comparison result whether the temperature state of the IGBT 3 is a high-temperature state.

The temperature detection voltage Vdi at the anode of the temperature detection diode Dt1 has a negative temperature characteristic, decreases which as the temperature of the IGBT 3 rises. Therefore, when the level of the temperature detection voltage Vdi becomes equal to or lower than the reference voltage Voh, the comparator cmp1 determines that the temperature state of the IGBT 3 is the high-temperature state, and outputs the temperature detection signal sg2 of the H level.

When the level of the temperature detection voltage Vdi becomes higher than the reference voltage Voh, the comparator cmp1 determines that the temperature state of the IGBT 3 is the ambient-temperature state, and outputs the temperature detection signal sg2 of the L level. The drive control unit 121 receives the temperature detection signal sg2 output from the temperature detection circuit 122, and controls the drive capability of the IGBT 3 by changing the output level of the drive voltage sg3 according to the level of the temperature detection signal sg2.

As described above, in the semiconductor device 100 of the reference example, the drive capability of the IGBT 3 is adjusted using the temperature detection signal sg2 of the IGBT 3 obtained based on the comparison result between the temperature detection voltage Vdi by the temperature detection diode Dt1 and the reference voltage Voh. Thus, even at a high temperature, a decrease in the switching speed of the IGBT 3 is suppressed, and an increase in switching loss is suppressed.

However, in the semiconductor device 100 configured as above, the temperature detection circuit 122 and the like are provided in the control IC 120 in order to adjust the drive capability of the IGBT 3. That is, additional circuits are needed, which leads to an increase in the circuit mounting scale.

Next, a semiconductor device of the present embodiment will be described. Since its upper arm and lower arm have the same configuration and operation, the configuration and operation of the upper arm will be described in detail below.

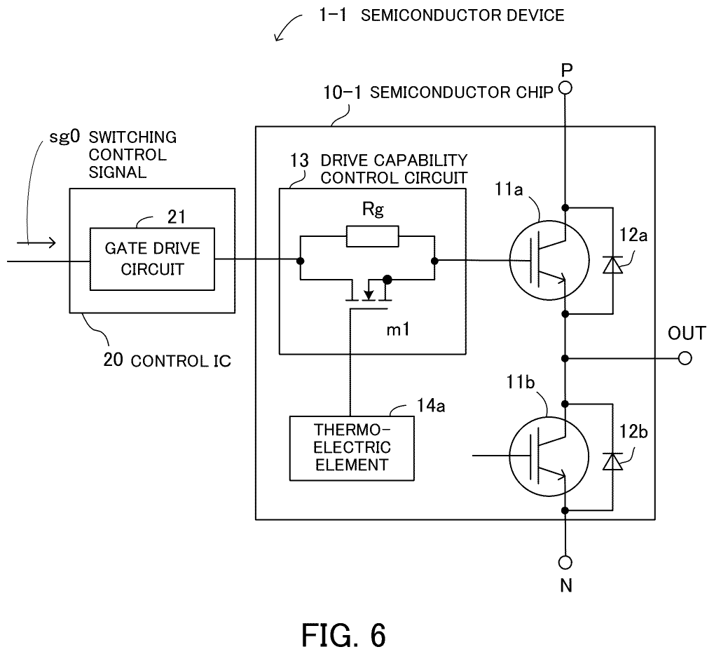

FIG. 6 illustrates an example of a first configuration of the semiconductor device according to the present embodiment. The semiconductor device 1-1 includes a semiconductor chip 10-1 and a control IC 20. The semiconductor chip 10-1 includes IGBTs 11a a and 11b and freewheel diodes (FWDs) 12a and 12b. Further, the semiconductor chip 10-1 includes a drive capability control circuit 13 and a thermoelectric element 14a corresponding to the voltage output element 1c. The control IC 20 includes a gate drive circuit 21.

The drive capability control circuit 13 includes a gate resistor Rg and an NMOS transistor m1 serving as a MOS transistor corresponding to the switch sw. The drive capability control circuit 13 may be disposed on the control IC 20 side. The thermoelectric element 14a is preferably disposed adjacent to the IGBT i in order to detect the temperature of the IGBT.

The connections between the structural elements are as follows. The collector of the IGBT 11a is connected to a positive terminal P and the cathode of the FWD 12a. The emitter of the IGBT 11a is connected to the anode of the FWD 12a, an output terminal OUT, the collector of the IGBT 11b, and the cathode of the FWD 12b. The emitter of the IGBT 11b is connected to the anode of the FWD 12b and a negative terminal N.

The output terminal of the gate drive circuit 21 is connected to one end of the gate resistor Rg and the drain (high potential terminal) of the NMOS transistor m1. The other end of the gate resistor Rg is connected to the source (low potential terminal) of the NMOS transistor m1 and the gate of the IGBT 11a. The gate (control terminal) of the NMOS transistor m1 is connected to the voltage output terminal of the thermoelectric element 14a.

The thermoelectric element 14a is an element that is disposed in the vicinity of the IGBT 11a and that converts the temperature of the IGBT 11a when the IGBT 11a is driven into a voltage (thermoelectric conversion), and outputs a voltage corresponding to the temperature of the IGBT 11a.

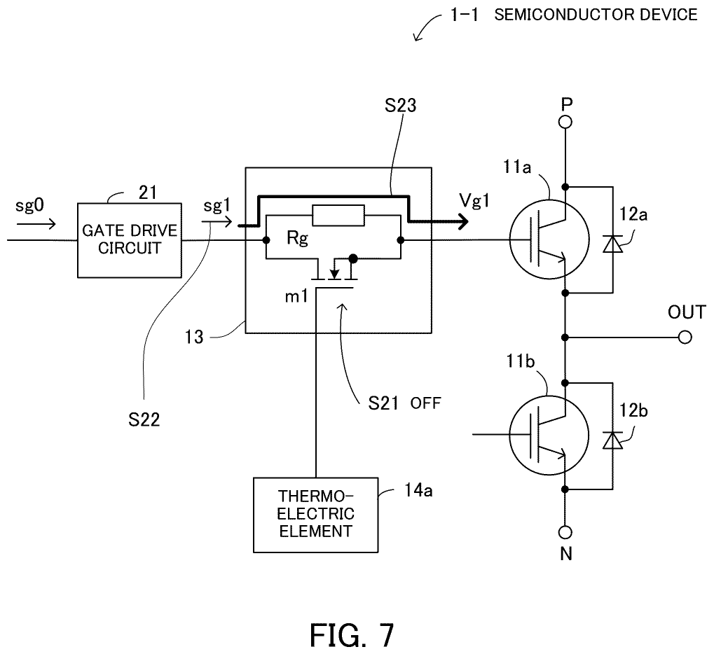

FIG. 7 is a diagram for describing the operation of the drive capability control when the IGBT is in the ambient-temperature state.

[Step S21] When the IGBT 11a is driven in the ambient-temperature state (first-temperature state), a voltage of a predetermined level output from the thermoelectric element 14a is at a low level, and thus the NMOS transistor m1 is turned off. The predetermined level corresponds to, for example, a threshold voltage level needed to turn on the NMOS transistor m1.

[Step S22] The gate drive circuit 21 outputs a drive signal sg1 for performing switching control of the IGBT 11a on the basis of a switching control signal sg0 received from the control unit.

[Step S23] The drive signal sg1 flows through the gate resistor Rg because the NMOS transistor m1 is off. Therefore, a gate drive voltage Vg1 (first gate drive voltage) based on the resistance value of the gate resistor Rg is output from the drive capability control circuit 13, and is input to the gate of the IGBT 11a.

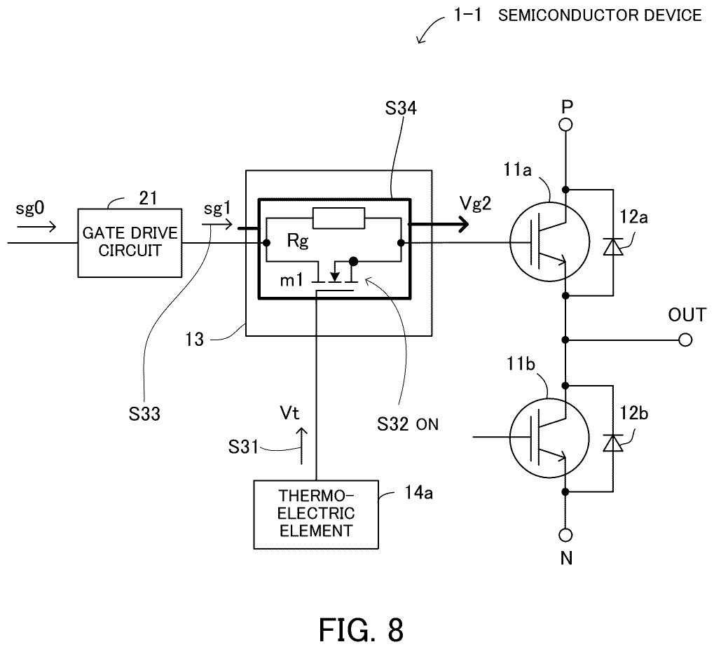

FIG. 8 is a diagram for describing the operation of the drive capability control when the IGBT is in a high-temperature state.

[Step S31] When the IGBT 11a is driven in the high-temperature state (second-temperature state), a voltage Vt of a predetermined level (high level) is output from the thermoelectric element 14a.

[Step S32] Since the voltage Vt of the predetermined level output from the thermoelectric element 14a to the gate of the NMOS transistor m1 is at the high level, the NMOS transistor m1 is turned on.

[Step S33] The gate drive circuit 21 outputs the drive signal sg1 for performing switching control of the IGBT 11a on the basis of the switching control signal sg0 received from the control unit.

[Step S34] Since the NMOS transistor m1 is on, the drive signal sg1 flows through both the gate resistor Rg and the NMOS transistor m1. Therefore, the gate drive voltage Vg2 (second gate drive voltage) based on the parallel combined resistance value of the gate resistor Rg and the on-resistance of the NMOS transistor m1 is output from the drive capability control circuit 13, and is input to the gate of the IGBT 11a.

As described above, in the semiconductor device 1-1, in the case where the IGBT 11a is detected to be driven at ambient temperature, the IGBT 11a is driven by the gate drive voltage Vg1 based on the resistance value of the gate resistor Rg. In the case where the IGBT 11a is detected to be driven at a high temperature, the NMOS transistor m1 is turned on by the voltage output from the thermoelectric element 14a. Therefore, the IGBT 11a is driven by the gate drive voltage Vg2 based on the parallel combined resistance value of the gate resistor Rg and the on-resistance of the NMOS transistor m1.

Since the parallel combined resistance value of the gate resistor Rg and the on-resistance of the NMOS transistor m1 is smaller than the resistance value of the gate resistor Rg alone, the gate drive voltage Vg2 is smaller than the gate drive voltage Vg1. Therefore, the switching speed at high temperature is higher than the switching speed at ambient temperature.

As described above, in the semiconductor device 1-1, the level of the gate drive voltage for the IGBT is switched depending on whether the temperature of the IGBT is the ambient temperature or the high temperature, so as to adjust the drive capability of the IGBT. This makes it possible to suppress, even at the high temperature, a decrease in the switching speed of the IGBT and an increase in the switching loss. Furthermore, the temperature of the IGBT is detected using the thermoelectric element as the temperature detection mechanism needed for adjusting the drive capability. Therefore, the circuit configuration is simpler than that of the semiconductor device 100 of the reference example, which enables a reduction in the circuit mounting scale.

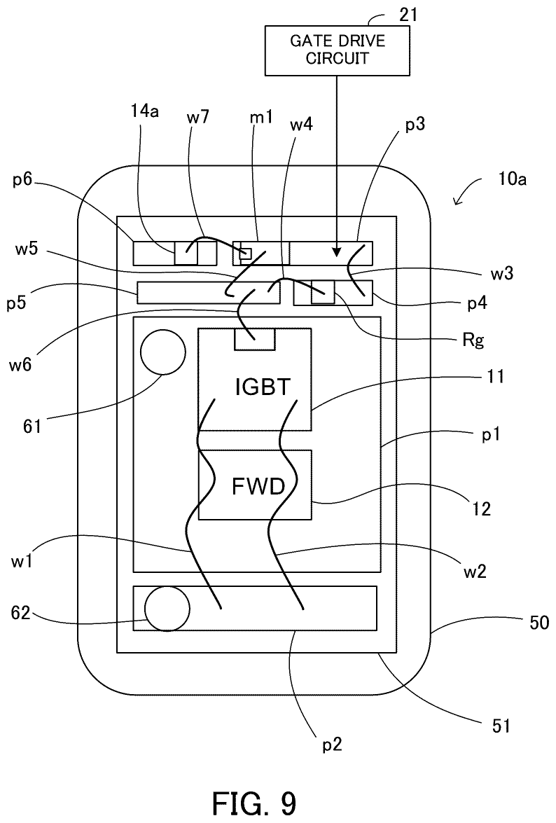

FIG. 9 illustrates a first mounting example of circuit components of a semiconductor chip. The semiconductor chip 10a includes a copper base 50, an insulating substrate 51, an IGBT 11, an FWD 12, a gate resistor Rg (chip resistor), and an NMOS transistor m1.

The insulating substrate 51 is bonded to the upper surface of the copper base 50 by a bonding material such as solder. Conductive patterns p1, p2, p3, p4, p5, and p6 are laid on the insulating substrate 51. The IGBT 11 and the FWD 12 are mounted on the conductive pattern p1.

The collector of the IGBT 11 is connected to an external terminal 61 (positive terminal P) and the cathode of the FWD 12 through the conductive pattern p1. The emitter of the IGBT 11 is connected to the anode of the FWD 12 through wires w1 and w2, and is further connected to an external terminal 62 (negative terminal N) through the wires w1 and w2 and the conductive pattern p2.

The drain of the NMOS transistor m1 is connected to the conductive pattern p3. The conductive pattern p3 is connected to the conductive pattern p4 through a wire w3, and one end of the gate resistor Rg is connected to the conductive pattern p4. The other end of the gate resistor Rg is connected to the conductive pattern p5 through a wire w4.

The conductive pattern p5 is connected to the source of the NMOS transistor m1 through a wire w5, and is further connected to the gate of the IGBT 11 through a wire w6. On the other hand, a thermoelectric element 14a is connected to the conductive pattern p6, and the voltage output terminal of the thermoelectric element 14a is connected to the gate of the NMOS transistor m1 through a wire w7.

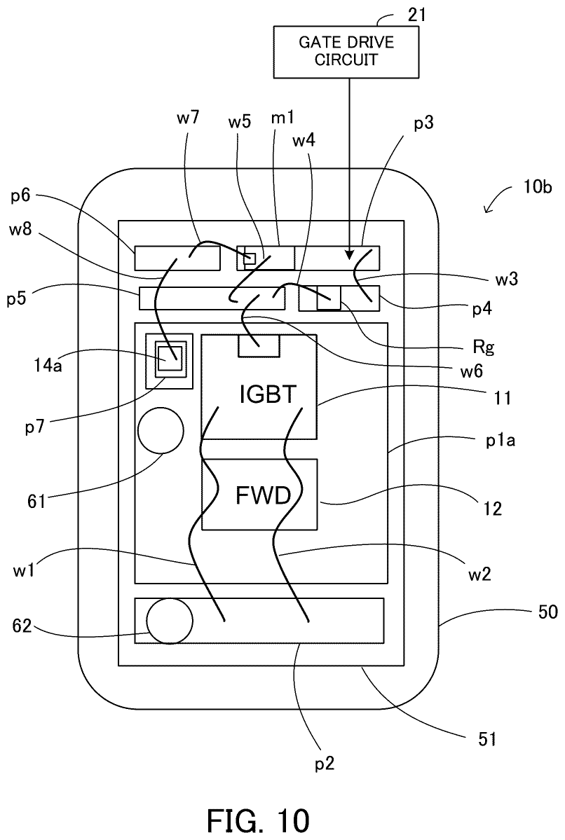

FIG. 10 illustrates a second mounting example of circuit components of a semiconductor chip. The semiconductor chip 10b includes a copper base 50, an insulating substrate 51, an IGBT 11, an FWD 12, a gate resistor Rg (chip resistor), and an NMOS transistor m1.

The insulating substrate 51 is bonded to the upper surface of the copper base 50 by a bonding material such as solder. Conductive patterns p1a, p2, p3, p4, p5, p6, and p7 are laid on the insulating substrate 51. The IGBT 11 and the FWD 12 are mounted on the conductive pattern p1a.

The collector of the IGBT 11 is connected to an external terminal 61 (positive terminal P) and the cathode of the FWD 12 through the conductive pattern p1a. The emitter of the IGBT 11 is connected to the anode of the FWD 12 through wires w1 and w2, and is further connected to an external terminal 62 (negative terminal N) through the wires w1 and w2 and the conductive pattern p2.

The drain of the NMOS transistor m1 is connected to the conductive pattern p3. The conductive pattern p3 is connected to the conductive pattern p4 through a wire w3, and one end of the gate resistor Rg is connected to the conductive pattern p4. The other end of the gate resistor Rg is connected to the conductive pattern p5 through a wire w4.

The conductive pattern p5 is connected to the source of the NMOS transistor m1 through a wire w5, and is further connected to the gate of the IGBT 11 through a wire w6. On the other hand, a thermoelectric element 14a is connected to the conductive pattern p7, and the voltage output terminal of the thermoelectric element 14a is connected to the conductive pattern p6 through a wire w8. The conductive pattern p6 is connected to the gate of the NMOS transistor m1 through a wire w7.

As described above, the thermoelectric element 14a, and the gate resistor Rg and the NMOS transistor m1 in the drive capability control circuit 13 are incorporated in the semiconductor chip, and the thermoelectric element 14a is disposed in the vicinity of the IGBT 11. Such mounting makes it possible to detect the temperature of the IGBT 11 with high efficiency, and to reduce the circuit mounting scale.

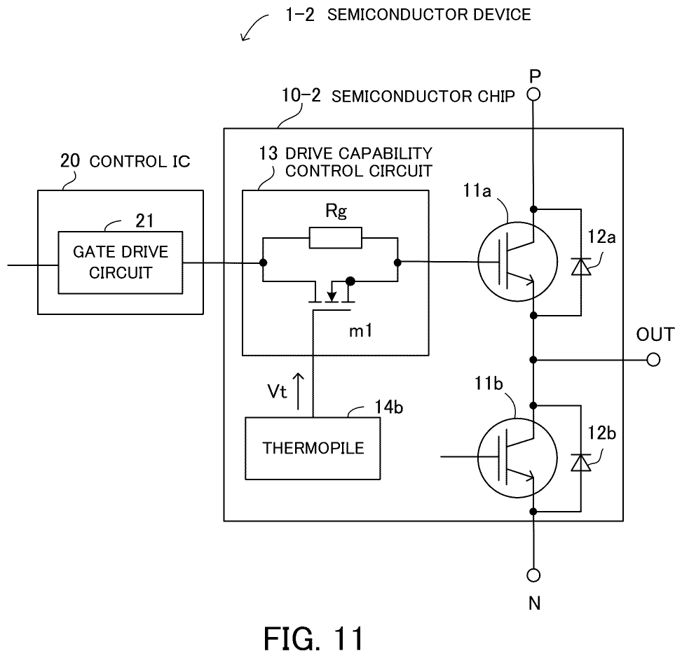

FIG. 11 illustrates an example of a second configuration of a semiconductor device according to the present embodiment. The semiconductor device 1-2 includes a semiconductor chip 10-2 and a control IC 20. The semiconductor chip 10-2 includes IGBTs 11a and 11b and FWDs 12a and 12b. Further, the semiconductor chip 10-2 includes a drive capability control circuit 13 and a thermopile 14b. The semiconductor device 1-2 uses a thermopile 14b instead of the thermoelectric element 14a, and the other configuration thereof is the same as that in FIG. 6.

The thermopile 14b is disposed near the IGBT 11a so as to be able to detect infrared rays emitted from the IGBT 11a when the IGBT 11a is driven. The thermopile 14b is an element that converts incident energy of infrared rays emitted from the IGBT 11a into electric energy and outputs a voltage corresponding to the temperature of the IGBT 11a. The drive capability control circuit 13 controls the drive capability of the IGBT 11a by switching the level of the gate drive voltage for the IGBT 11a according to the voltage Vt output from the thermopile 14b.

As described above, also in the semiconductor device 1-2, the level of the gate drive voltage for the IGBT is switched depending on whether the temperature of the IGBT is the ambient temperature or the high temperature, so as to control the drive capability of the IGBT. This makes it possible to suppress a decrease in the switching speed of the IGBT and an increase in the switching loss during high-temperature driving of the IGBT. In addition, the temperature of the IGBT is detected using the thermopile as the temperature detection mechanism needed for adjusting the drive capability. Therefore, the circuit configuration is simpler than that of the semiconductor device 100 of the reference example, which enables a reduction in the circuit mounting scale.

According to one aspect, it is possible to adjust the drive capability of a switching element on the basis of the temperature of the switching element to reduce switching loss, and to reduce the circuit mounting scale.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a switching element having a gate;
a gate drive circuit configured to drive the switching element;
a voltage output element configured to detect a temperature of the switching element when the switching element is driven and output a voltage corresponding to the temperature; and
a drive capability control circuit configured to control a drive capability of the switching element by changing a gate drive voltage to be applied to the gate of the switching element based on the voltage outputted by the voltage output element.

2. The semiconductor device according to claim 1, wherein
the drive capability control circuit includes a gate resistor and a switch connected in parallel to each other, the switch being configured to be turned on and off in response to the voltage outputted by the voltage output element,
in response to the switching element being in a first-temperature state corresponding to a first temperature, the drive capability control circuit
turns off the switch,
generates a first gate drive voltage based on a resistance value of the gate resistor, and
applies the first gate drive voltage to the gate to drive the switching element with a first drive capability, and
in response to the switching element being in a second-temperature state corresponding to a second temperature higher than the first temperature, the drive capability control circuit
turns on the switch,
generates a second gate drive voltage based on the resistance value of the gate resistor and an on-resistance of the switch, and
applies the second gate drive voltage to the gate to drive the switching element with a second drive capability.

3. The semiconductor device according to claim 2, wherein
the switch is a metal oxide semiconductor (MOS) transistor having a high potential terminal, a low potential terminal and a control terminal,
the gate drive circuit has an output terminal from which a drive signal is output,
the gate resistor has
a first end connected to the high potential terminal of the MOS transistor and the output terminal of the gate drive circuit, and
a second end connected to the low potential terminal of the MOS transistor and the gate of the switching element, and
the voltage output element has an output terminal from which the voltage is output, the output terminal of the voltage output element being connected to the control terminal of the MOS transistor.

4. The semiconductor device according to claim 1, wherein the voltage output element includes a thermoelectric element that converts the temperature of the switching element into the voltage.

5. The semiconductor device according to claim 1, wherein the voltage output element includes a thermopile that converts incident energy of infrared rays emitted from the switching element into electric energy.

6. The semiconductor device according to claim 1, wherein the voltage output element and the drive capability control circuit are mounted on a chip where the switching element is mounted.
